(19) United States
(12) Patent Application Publication
(10) Pub. No.: US 2022/0339744 A1
(43) Pub. Date: Oct. 27, 2022

(54) LOW RESIDUE NO-CLEAN FLUX COMPOSITION AND METHOD FOR FABRICATING SEMICONDUCTOR PACKAGE USING THE SAME

(71) Applicants: SK hynix Inc., Icheon-si Gyeonggi-do (KR); Evertech Enterprise Co., Ltd., Hwaseong-city Gyeonggi-do (KR)

(72) Inventors: Hyun Suk LEE, Icheon-si Gyeonggi-do (KR); Sang Hoon YOON, Icheon-si Gyeonggi-do (KR); Gwang Hyeon GOH, Icheon-si Gyeonggi-do (KR); Jang Rak CHOI, Hwaseong-city Gyeonggi-do (KR); Yong Ju SEO, Hwaseong-city Gyeonggi-do (KR); Chang Il YOO, Hwaseong-city Gyeonggi-do (KR); Seung Hoon LEE, Hwaseong-city Gyeonggi-do (KR); Da Been PARK, Hwaseong-city Gyeonggi-do (KR)

(73) Assignees: SK hynix Inc., Icheon-si Gyeonggi-do (KR); Evertech Enterprise Co., Ltd., Hwaseong-city Gyeonggi-do (KR)

(21) Appl. No.: 17/474,805

(22) Filed: Sep. 14, 2021

(30) Foreign Application Priority Data
Apr. 15, 2021 (KR) 10-2021-0049322

(51) Int. Cl. B23K 35/362; B23K 1/00; B23K 1/20; H01L 23/00

(52) U.S. Cl. CPC B23K 35/362; B23K 1/0016; B23K 1/203; H01L 24/81; H01L 24/92; B23K 2101/40

(57) ABSTRACT

A flux composition includes an aromatic resin including one benzene ring and one or two hydroxyl (—OH) groups, an activator selected from a group consisting of a dicarboxylic acid and a dicarboxylic anhydride, and a solvent.

### CROSS-REFERENCE TO RELATED APPLICATION

This application claims priority under 35 U.S.C. § 119 to Korean Patent Application No. 10-2021-0049322 filed on Apr. 15, 2021, which is incorporated herein by reference in its entirety.

### BACKGROUND

### 1. Technical Field

Various embodiments relate generally to a no-clean flux composition that can be used for fabricating a semiconductor package such as a flip chip package, and more particularly, to a low residue no-clean flux composition and a method for fabricating a semiconductor package using the same.

### 2. Related Art

Electronic products are evolving to process larger amounts of data while having smaller form factors. Thus, in the field of semiconductor packages such as ball grid arrays (BGAs), flip chip ball grid arrays (FCBGAs), wafer level packages (WLPs) and a through silicon vias (TSVs), technologies capable of achieving a high degree of integration, thinner films, and light weight have been developed. Also, the number of inputs and outputs (I/O) per unit area is increased due to the decrease in bump sizes and a pitch.

Because BGA, FCBGA, and TSV package technologies have advantages of minimizing a signal travel distance and power consumption through solder bonding, and maximizing a package space, the demand for such technologies is continuously increasing. Accordingly, there is an increasing demand for improving properties of a flux material for bonding fine solder bumps.

### SUMMARY

In an embodiment, a flux composition includes: an aromatic resin including one benzene ring and one or two hydroxyl (—OH) groups; an activator selected from a group consisting of a dicarboxylic acid and a dicarboxylic anhydride; and a solvent.

In an embodiment, a method for fabricating a semiconductor package includes a soldering process using a flux composition, wherein the flux composition includes: an aromatic resin including one benzene ring and one or two hydroxyl (—OH) groups; an activator selected from a group consisting of a dicarboxylic acid and a dicarboxylic anhydride; and a solvent.

In an embodiment, a method for fabricating a semiconductor package includes: forming solder bumps over an active surface of a chip; applying a flux composition over a surface of the solder bumps; providing a substrate having a first surface where first pads are formed and a second surface where second pads are formed; aligning the chip with the substrate such that the solder bumps of the chip are in contact with the first pads of the substrate; and performing a reflow process on the aligned chip and substrate. The flux composition includes: an aromatic resin including one benzene ring and one or two hydroxyl (—OH) groups; an activator selected from a group consisting of a dicarboxylic acid and a dicarboxylic anhydride; and a solvent.

### BRIEF DESCRIPTION OF THE DRAWINGS

FIGS. 1A to 1C are cross-sectional views for describing a method for fabricating a flip chip package in accordance with a comparative example.

FIGS. 2A to 2F are cross-sectional views illustrating a method for fabricating a flip chip package in accordance with an embodiment of the disclosed technology.

FIG. 3 shows a block diagram illustrating an electronic system employing a memory card including a semiconductor package, according to an embodiment.

FIG. 4 shows a block diagram illustrating another electronic system including a semiconductor package, according to an embodiment.

### DETAILED DESCRIPTION

Various examples and implementations of the disclosed technology are described below in detail with reference to the accompanying drawings.

Various embodiments may be directed to a semiconductor package which can prevent a defect and facilitate a fabrication process, and a method for fabricating the same.

The drawings may not necessarily be to scale, and in some instances, proportions of at least some of the structures in the drawings may have been exaggerated in order to clearly illustrate certain features of the described examples or implementations. In presenting a specific example in a drawing or description having two or more layers in a multi-layer structure, the relative positional relationship of such layers or the sequence of arranging the layers as shown reflects a particular implementation for the described or illustrated example, and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

Prior to the description of embodiments in accordance with the disclosed technology, a method for fabricating a semiconductor package using conventional technology and its problems will be described.

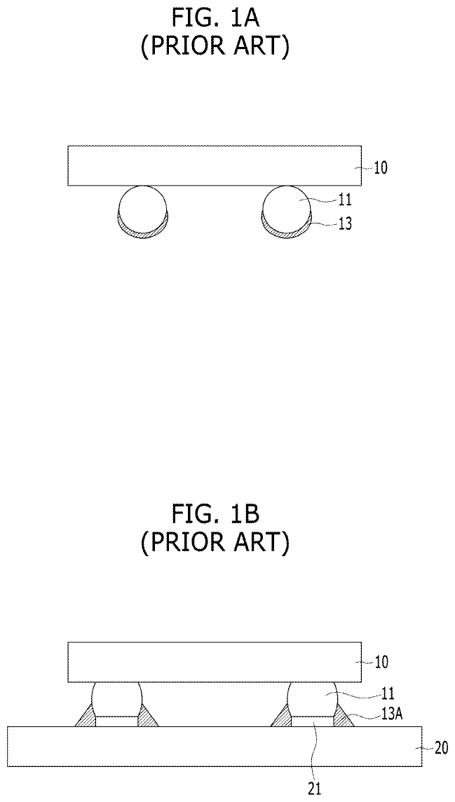

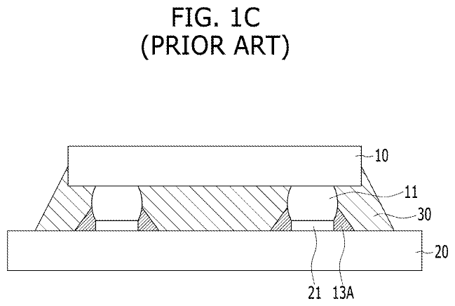

FIGS. 1A to 1C are cross-sectional views for explaining a method for fabricating a flip chip package in accordance with a comparative example.

A flip chip package uses a type of wireless bonding. In the flip chip package, attaching a semiconductor chip to a circuit board can be achieved by fusion using bumps that are electrode patterns on a surface of the chip without using an additional connection structure or intermediate medium such as a metal lead. The flip chip package has advantages in that a size and a weigh of the chip can be decreased, and a smaller distance between electrodes can be achieved.

Referring to FIG. 1A, a plurality of bumps 11 may be formed over an active surface of a chip 10, which is shown flipped. The bumps 11 may be formed on pads (not shown) over the active surface of the chip 10 through a wafer bumping process. The bumps 11 may serve to bond the chip 10 to a substrate (see, reference numeral 20 of FIG. 1B) and transmit an electrical signal between the chip 10 and the substrate 20.

The bumps 11 may be formed of lead-free solder, or may be formed in a shape in which lead-free solder is covered on a copper pillar. Bonding of the bumps 11 may be performed by soldering while passing through a furnace, or by thermal compression using a non-conductive paste (NCP) or a non-conductive film (NCF).

Then, a flux 13 may be applied to a surface of the bumps 11.

The flux 13 may serve to prevent oxidation of a surface to be bonded, thereby ensuring a complete bonding. That is, the flux 13 may remove an oxide on the surfaces of the bumps 11 and bonding pads (see, reference numeral 21 of FIG. 1B) and provide a tacky surface for maintaining the chip 10 over the substrate 20 in a subsequent reflow process so that a complete bonding may be formed between the bumps 11 and the bonding pads 21.

The flux 13 may usually include three components: a solvent, a vehicle, and an activator. The solvent may allow the flux 13 to be uniformly spread over the surface of the bumps 11, and may include, for example, an alcohol. The solvent may be evaporated in a preheating step performed before the reflow process, whereby the flux 13 may be uniformly applied over the bumps 11. As a temperature further increases, the vehicle may flow together with the activator. The activator may remove the oxide by reduction, and both the vehicle and the activator may be evaporated. The vehicle may include a solvent with a high boiling point such as an aliphatic alcohol, and the activator may include an acid such as a carboxylic acid.

The application of the flux 13 may be performed by dipping the bumps 11 into the flux 13, or by a brush distribution method.

Referring to FIG. 1B, the chip 10 may be aligned with the substrate 20 so that the bumps 11 over the chip 10 may be properly aligned and contacted with the bonding pads 21 over the substrate 20.

Then, the reflow process may be performed. During the reflow process, a resultant structure may be heated to a temperature equal to or higher than a melting point of the solder. Thus, the solder of the bumps 11 may be dissolved, thereby forming a metallurgical bond to the bonding pads 21. A module including the substrate 20 and the chip 10 may be formed by the metallurgical bond.

After the reflow process, a flux residue 13A may remain in a region between the substrate 20 and the chip 10 in the module. The flux residue 13A may include residues from the vehicle, the activator, and reaction by-products of the reduction reaction.

Referring to FIG. 1C, an underfill layer 30 may be formed in a gap between the substrate 20 and the chip 10.

The underfill layer 30 may serve to protect the chip 10 and lines during a subsequent process, and to improve the reliability of a line system.

The underfill layer 30 may be formed of a resin, for example, an epoxy resin.

According to the method for fabricating the flip chip package in accordance with the comparative example shown in FIGS. 1A to 1C, a large amount of the flux residue 13A may remain in the region between the substrate 20 and the chip 10 after the reflow process. The remaining flux residue 13A may cause ion migration in a subsequent process or peeling from the underfill layer 30, thereby causing poor reliability.

To solve this problem, a cleaning process for removing the flux residue 13A may be performed after the reflow process. However, because solvents used in the cleaning process are highly flammable, harmful to the environment, and sometimes carcinogenic, the cleaning process using the solvent requires highly specialized equipment and should be equipped with a special filtration system. Therefore, it is expensive to carry out the cleaning process.

In addition, although the cleaning process is performed, it may be difficult to completely remove the flux residue 13A due to a decrease in bump size and pitch. The reliability problem caused by the remaining flux residue 13A continues to occur as the bump size and the pitch become much smaller according to technology advancement and integration.

Further, as the bump size and pitch are decreased, a highly active flux having a high ability for removing oxides and a high activation ability may be needed. Such a highly active flux has a high solid content, which causes a large amount of the residue remaining after the reflow process.

Embodiments of the disclosed technology provide a no-clean low residue flux composition with a high activity and a method for fabricating a semiconductor package using the same, in which a flux residue can be minimized after a reflow process so that a separate cleaning process is not required and the poor reliability problem caused by the flux residue can be overcome.

In accordance with an embodiment of the disclosed technology, a no-clean low residue flux composition with a high activity for use in a semiconductor package process is provided.

The flux composition may be used in a soldering process in the semiconductor package process. For example, the flux composition may serve to remove an oxide film formed on a surface of bumps, solder balls, pads, or contacts, bond the solder balls or the bumps to a substrate, or form solder bumps on a wafer.

For example, the flux composition may be used in a flip chip package process. The flux composition may serve to remove an oxide film on surfaces of the solder bumps on a chip and surfaces of the pads on the substrate, and provide a tacky surface for maintaining the chip over the substrate during a subsequent reflow process, allowing for a bond between the solder bumps and the pads.

The semiconductor package process to which the flux composition in accordance with the embodiment can be applied may include, but is not limited to, BGA, FCBGA and TSV package technologies.

The flux composition in accordance with an embodiment may be a no-clean composition, in which flux residue might not remain or may hardly remain, and thus there is no need for a separate cleaning process.

The flux composition in accordance with an embodiment may be a highly active composition that can be used for bonding fine solder bumps having a decreased bump size and pitch.

In the embodiment, each component included in the flux composition may be selected such that the composition can exhibit overall optimal effects in terms of viscosity, tackiness, soldering characteristics, and residue minimization. Although it is possible to improve an individual characteristic among the above characteristics by suitably selecting any one component, other characteristics can be deteriorated as a consequence. Therefore, it is desirable to select optimum components, which can lead to the optimum effect in consideration of the above characteristics together. In an embodiment, each component included in the flux composition may be determined in consideration of balancing various aspects of device performance.

The flux composition in accordance with an embodiment may include an aromatic resin, an activator, and a solvent.

An aromatic resin may serve to impart sufficient viscosity and sufficient tackiness during the soldering process, minimizing residues remaining after the reflow process due to its low boiling point and high volatilization characteristics, and minimizing contamination of reflow equipment during volatilization.

Conventional low residue no-clean flux compositions include a rosin as a main component. Rosin is a natural resin obtained by distillation of pine resin and contains abietic acid as a main component and various rein acids. Because the rosin has low reactivity with moisture and a high acid value required for soldering, it has been commonly used in flux composition. However, rosin has a high viscosity and a high solid content so that a large amount of residues remain after the reflow process. When a large amount of the flux residue remains, peeling may occur after curing an underfill layer so that the solder bumps and the underfill layer are not combined. Thus, it is impossible to prevent the solder bumps from the external impact. Therefore, solder bump cracks or short circuits may occur due to thermal shock or a mismatch between coefficients of thermal expansion (CTE), thereby causing poor reliability.

Unlike the conventional low residue no-clean flux composition, the aromatic resin included in the flux composition in accordance with an embodiment has a viscosity which is required for soldering and is sufficient to impart a tackiness, and volatilizes during the reflow process. Therefore, an amount of the residue remaining after the reflow process can be decreased or minimized. Accordingly, there is no need to perform a separate cleaning process after the reflow process. Further, it is possible to suppress a problem of poor reliability due to the flux residue.

In an embodiment, the aromatic resin may have a high vapor pressure and thus have excellent volatility, and at the same time, have a viscosity sufficient for imparting a tackiness and viscosity required for soldering.

In an embodiment, the aromatic resin may completely or to substantially completely volatilize during the reflow process.

In an embodiment, the aromatic resin may include one benzene ring, and one or two hydroxyl (—OH) groups.

In an embodiment, the aromatic resin may be selected from a group consisting of compounds of Formulae 1 to 5 as follows:

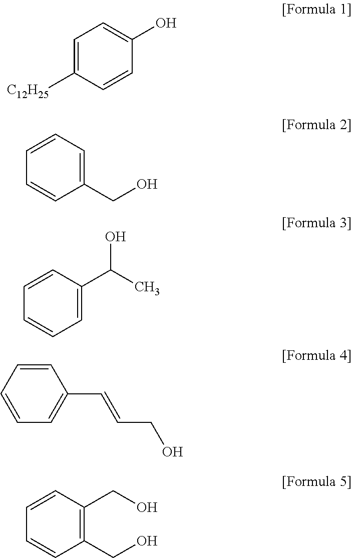

Names of compounds of Formulae 1 to 5 are as follows:

### Compound of Formula 1: 4-Dodecylphenol

Compound of Formula 2: Benzyl alcohol
Compound of Formula 3: Methyl phenyl carbinol
Compound of Formula 4: Cinnamyl alcohol

Compound of Formula 5: Phthalyl alcohol

In an embodiment, the aromatic resin may include a compound selected from the group consisting of compounds of Formulae 1 to 5, alone or in combination of two or more thereof.

In an embodiment, the aromatic resin may be included in the flux composition in an amount of 60-90 percent by weight (wt %), preferably 65-90 wt %, preferably 70-90 wt %, preferably 75-90 wt %, preferably 80-90 wt %, and preferably 85-90 wt %, based on a total weight of the flux composition. When the amount of the aromatic resin is less than the above range, the flux residue remaining after the reflow process may be increased so that peeling may occur after curing the underfill layer and the solder bumps may not be protected from the external impact, causing poor reliability such as solder cracks or short circuits. When the amount of the aromatic resin is greater than the above range, a sufficient solder bonding characteristic may not be achieved, thereby causing solder bonding defects.

The activator may serve to remove an oxide film formed on surfaces to be bonded, for example, surfaces of the bumps, the solder balls, and the pads, by reduction, and activate the surfaces so as to exhibit a solder bonding characteristic. Moreover, the activator may volatilize before reaching a dwell time region during the reflow process so that the residue of the flux composition after the reflow process can be minimized and does not interfere with curing of an underfill layer material.

Conventional low residue no-clean flux compositions commonly include an acid such as glutaric acid, succinic acid, diglycolic acid, polyglycolic acid, or glycolic acid as the activator. However, when such an acid remains as a residue after the reflow process, the residue may interfere with curing of the underfill layer material because it has little or no reactivity with an epoxy usually used as the underfill layer material. That is, peeling may occur after curing the underfill layer material so that the solder bumps and the underfill layer are not combined. Thus, it is impossible to prevent the solder bumps from the external impact. Therefore, solder bump cracks or short circuits may occur due to a thermal shock or a mismatch between coefficients of thermal expansion (CTE), thereby causing poor reliability.

Unlike the conventional low residue no-clean flux composition, the activator included in the flux composition in accordance with an embodiment can remove an oxide film formed on surfaces of the bumps, the solder balls, and the pads by reduction, activate the surfaces, and volatilize during the reflow process. Therefore, the residue of the flux composition after the reflow process can be decreased or minimized and does not interfere with curing of the underfill layer material in a subsequent process. Accordingly, there is no need to perform a separate cleaning process after the reflow process. Further, it is possible to mitigate or suppress a problem of poor reliability due to the flux residue.

In an embodiment, the activator can remove an oxide film on the solder bumps by reduction before reaching a dwell time during the reflow process, and can completely or substantially completely volatilize during the reflow process.

In an embodiment, the activator may be selected from a group consisting of a dicarboxylic acid and a dicarboxylic anhydride.

In an embodiment, the activator may be selected from a group consisting of compounds of Formulae 6 to 9 as follows:

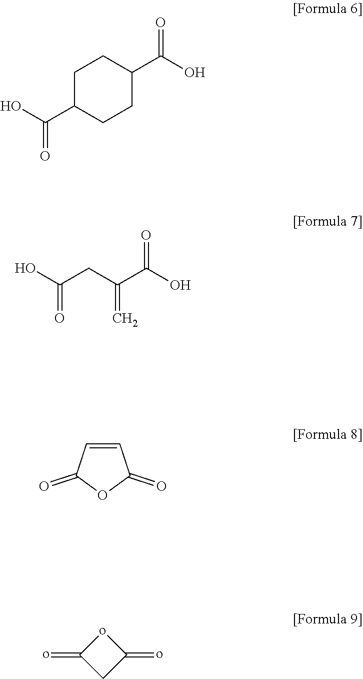

Names of compounds of Formulae 6 to 9 are as follows:

Compound of Formula 6: 1,4-Cyclohexanedicarboxylic acid
Compound of Formula 7: Itaconic acid
Compound of Formula 8: Maleic anhydride
Compound of Formula 9: Malonic anhydride

In an embodiment, the activator may include a compound selected from the group consisting of compounds of Formulae 6 to 9, alone or in combination of two or more thereof.

In an embodiment, the activator may be included in the flux composition in an amount of 1-10 wt %, preferably 2-10 wt %, preferably, 3-10 wt %, preferably 4-10 wt %, and preferably 5-10 wt %, based on a total weight of the flux composition. When the amount of the activator is less than the above range, because the effect of removing the oxide film on the surfaces of the bumps, the solder balls, or the pads and activating the surfaces is not sufficient, solder bonding defects may occur. When the amount of the activator is greater than the above range, because a problem of storage stability of the flux composition may occur, a separate refrigeration facility may be required, thereby causing a cost problem.

A specific combination of the aromatic resin and the activator included in the flux composition in accordance with an embodiment allows for achieving a good wetting characteristic between the surfaces to be bonded, for example, between the solder bumps and the pads, thereby exhibiting a good soldering characteristic. That is, by using a specific combination of the aromatic resin and the activator, it is possible to eliminate or reduce surface tension at an interface to be bonded so as to exhibit an excellent wetting characteristic and further improving the soldering characteristic.

Moreover, the viscosity and the tackiness of the flux composition can be controlled within a wide range by appropriately controlling the combination of the aromatic resin and the activator. For example, by controlling the relative amounts of the aromatic resin and the activator, and/or by changing at least one of the compounds used as the aromatic resin and the activator. Wafer chips have various sizes and thicknesses, and the bump size and the pitch vary depending on device types. Accordingly, ranges of the viscosity and the tackiness required for the flux composition may vary depending on types of wafer chips and process characteristics. Therefore, the flux composition having the viscosity and the tackiness in a specific narrow range cannot cover a margin for various processes. The flux composition in accordance with an embodiment can exhibit a wide range of viscosity and tackiness according to the combination of the aromatic resin and the activator. Thus, in the embodiment, it is possible to exhibit the viscosity and the tackiness that can satisfy the requirements according to the types of wafer chips or the process characteristics by appropriately controlling the combination of the aromatic resin and the activator.

The solvent may allow the flux composition to be uniformly spread over the surfaces of the solder bumps so that the flux composition may be uniformly applied and characteristics of the flux composition may be uniformly exhibited.

In an embodiment, the solvent may include any solvent used in the art to prepare the flux composition.

In an embodiment, the solvent may include isopropyl alcohol, ethanol, acetone, toluene, xylene, ethyl acetate, monoglycol ether, butyl carbitol, cellosolve, butyl cellosolve, glycol ether, hexyldiglycol, (2-ethylhexyl)diglycol, phenylglycol, octanediol, α-terpineol, propylene glycol, β-terpineol, tetraethylene glycol dimethyl ether, tris(2-ethylhexyl) trimellitate, bis(2-ethylhexyl) sebacate, diethylene glycol monohexyl ether, diethylene glycol monobutyl ether, tripropylene glycol monobutyl ether, or a combination thereof.

In an embodiment, the solvent may be included in the flux composition in an amount of 5-40 wt %, preferably 5-35 wt %, preferably 5-30 wt %, preferably 5-25 wt %, preferably 5-20 wt %, and preferably 5-15 wt %, based on a total amount of the flux composition. When the amount of the solvent is less than the above range, the viscosity of the flux composition may become too high and workability may be decreased. When the amount of solvent is greater than the above range, the viscosity of the flux composition may become too low and the applied amount of the flux composition is insufficient, which may cause the occurrence of solder bonding defects.

In an embodiment, the flux composition may further include an additive for improving characteristics.

The low residue no-clean flux composition with a high activity can be applied to semiconductor package processes such as BGA, FCBGA and TSV package processes so as to be used for fine solder bump bonding or solder bump formation in which the size and the pitch become smaller. According to the no-clean flux composition in accordance with an embedment, it is possible to effectively remove the oxide film on the solder bumps, exhibit sufficient viscosity, sufficient tackiness, and solder bonding characteristics, and minimize the residue after the reflow process.

In an embodiment, in the flux composition in accordance with an embodiment, an amount of the residue after the reflow process may be 6.0 wt % or less based on a total weight of the flux composition.

As such, because the residue remaining after the reflow process can be reduced or minimized, there is no need to perform a separate cleaning process after the reflow process. Moreover, curing of the underfill layer material in a subsequent process is not interfered. Therefore, it is possible to mitigate or suppress peeling of the underfill layer material and a problem of poor reliability such as solder cracks or short circuits.

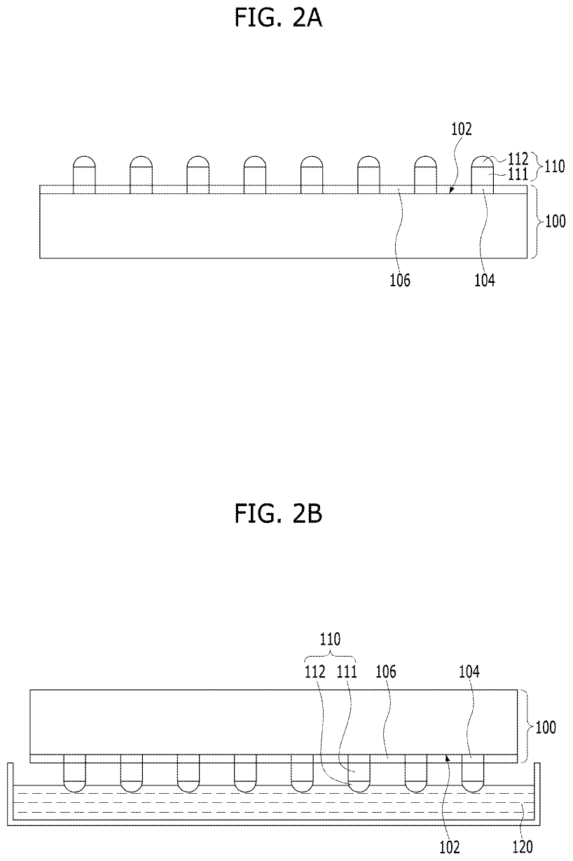

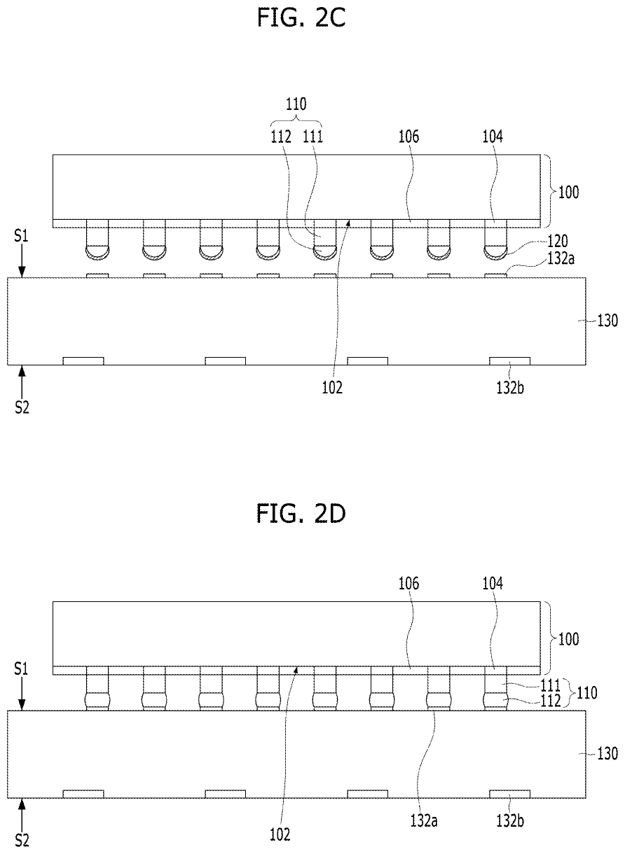

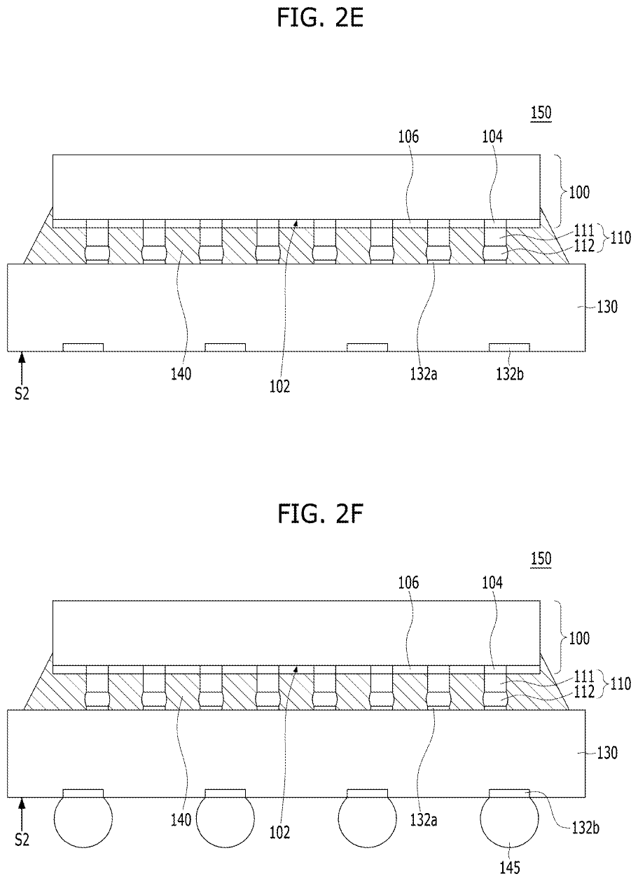

Hereinafter, a method for fabricating a semiconductor package using a flux composition in accordance with an embodiment indicated above will be described with reference to FIGS. 2A to 2F.

FIGS. 2A to 2F are cross-sectional views for describing a method for fabricating a flip chip package in accordance with an embodiment of the disclosed technology. Because the flux composition has been described in detail above, a repeated description thereof will be omitted here.

Referring to FIG. 2A, a chip 100 having an active surface 102 is shown.

The chip 100 may be a semiconductor chip and include silicon or gallium arsenic (GaAs).

A passivation layer 106 may be formed over the active surface 102 of the chip 100. The passivation layer 106 may serve to protect the chip 100 while leaving bonding pads 104 of the chip 100 exposed.

The bonding pads 104 may include a metal. In an embodiment, the bonding pads 104 may include a stack consisting of a Ni layer and an Au layer; a stack consisting of a Cr layer, a Cu layer, and an Au layer; a stack consisting of a TiW layer and a Cu layer; a stack consisting of a Ti layer and a Cu layer; or a stack consisting of a TiW layer and an Au layer.

Solder bumps 110 may be formed over the bonding pads 104 of the chip 100.

The solder bumps 110 may include a conductive pillar 111 and solder 112 disposed over the conductive pillar 111.

The conductive pillar 111 may include copper (Cu), gold (Au), platinum (Pt), titanium (Ti), nickel (Ni), or aluminum (Al), or a combination thereof, or an alloy containing such metals and another element.

In an embodiment, the conductive pillar 111 may include a copper element, impurity-containing copper, or a copper alloy. The copper alloy may include other elements such as tantalum (Ta), indium (In), tin (Sn), manganese (Mn), chromium (Cr), titanium (Ti), germanium (Ge), strontium (Sr), platinum (Pt), magnesium (Mg), aluminum (Al), zirconium (Zr), or a combination thereof.

The conductive pillar 111 may be formed by using an electroplating process, a physical vapor deposition (PVD) process, a chemical vapor deposition (CVD) process, an electrolytic plating process, or a combination thereof.

The solder 112 may be formed over the conductive pillar 111.

The solder 112 may include tin (Sn), lead (Pb), silver (Ag), bismuth (Bi), copper (Cu), gold (Au), aluminum (Al), arsenic (As), iron (Fe), nickel (Ni), antimony (Sb), or a combination thereof.

The solder 112 may be formed by using an electroplating process or other processes.

In the embodiment, the solder bumps 110 are formed in a cylindrical shape in which the solder 112 is formed over the conductive pillar 111. In another embodiment, the solder bumps 110 may be formed in a spherical shape including the solder.

In an embodiment, an under bump metallurgy (UBM) layer (not shown) may be formed between each of the bonding pads 104 and the corresponding solder bump 110. The UBM layer may serve to increase bonding reliability between the bonding pads 104 and the solder bumps 110 and prevent any contaminants in the solder bumps 110 from diffusing to the chip 100 through the bonding pads 104.

Referring to FIG. 2B, a dipping process may be performed in order to apply a flux composition 120 to a surface of the solder bumps 110.

The dipping process may include providing a vessel filled with the flux composition 120. Thereafter, with the active surface 102 of the chip facing down, the chip 100 may be brought into contact with the composition 120 so that the flux composition 120 may adhere to the surface of the solder bumps 110.

Then, the chip 100 may be lifted away from the vessel with the active surface 102 still facing downward to prevent the flux composition 120 from flowing onto the active surface 102.

In an embodiment, the flux composition 120 is applied by a dipping process. In another embodiment, the flux composition 120 may be applied to the solder bumps 110 by various methods known in the art.

Referring to FIG. 2C, the chip 100 may be disposed over a substrate 130. The chip 100 may be aligned with the substrate 130 such that the solder bumps 110 on the chip 100 are positioned over first pads 132a on the substrate 130.

The substrate 130 may be a semiconductor packaging substrate such as a printed circuit board (PCB) and include a ceramic material, an organic material, or a combination thereof.

The substrate 130 may have a first surface S1 and a second surface S2. A plurality of first pads 132a may be formed over the first surface S1, and a plurality of second pads 132b may be formed over the second surface S2.

Materials included in the first pads 132a and the second pads 132b may vary depending on a material included in the substrate 130. For example, when the substrate 130 includes a ceramic material, the first pads 132a and the second pads 132b may be a stack including a Ni layer and a Cu layer. When the substrate 130 includes an organic material, the first pads 132a and the second pads 132b may include a Cu layer.

Because the flux composition 120 is in a liquid state, the solder bumps 110 may make direct contact with the first pads 132a.

Referring to FIG. 2D, each of the solder bumps 110 on the chip 100 may be bonded to each of the first pads 132a, respectively, over the substrate 130.

The bonding of the solder bumps 110 and the first pads 132a may be achieved by performing a reflow process. The reflow process may be a process of melting the solder 112 to form a metallurgical bond by heating in a high temperature environment, for example, a furnace or an oven at a temperature greater than or equal to a melting point of the solder 112. After the reflow process, the chip 100 and the substrate 130 may be electrically and mechanically connected with each other through the solder bumps 110. That is, after the reflow process, the solder bumps 110 are bonded to the first pads 132a to form an electrical coupling therebetween.

During the reflow process, the flux composition 120 can remove an oxide film on surfaces of the solder bumps 110 and the first pads 132a by reduction, and activate these surfaces. Therefore, the flux composition 120 can exhibit an excellent viscosity, an excellent tackiness and soldering characteristics so as to form a good bond between the solder bumps 110 and the first pads 132a. Moreover, even if the flux composition 120 is applied to fine solder bumps having a much smaller bump size and pitch, it can exhibit a high activity. Further, during the reflow process, the aromatic resin, the activator, and the solvent included in the flux composition 120 are substantially completely volatilized, allowing for minimizing a residue after the reflow process. Therefore, a separate cleaning process might not be required after the reflow process, and curing of the underfill layer material is not interfered in a subsequent process. As a result, problems of peeling of the underfill layer material and poor reliability such as solder cracks or short circuits can be mitigated or prevented.

Referring to FIG. 2E, an underfill layer 140 may be formed in a gap between the chip 100 and the substrate 130.

The underfill layer 140 may serve to protect the chip 100 and lines during a subsequent process and improve reliability of line systems.

The underfill layer 140 may include an epoxy resin.

In an embodiment, the underfill layer 140 may cover a back surface of the chip 100.

Referring to FIG. 2F, an array of solder balls 145 may be formed over the second pads 132b on the second surface S2 of the chip 100 for electrically connecting with other devices or the substrate.

Referring to FIGS. 2E and 2F, a chip package 150 may include the substrate 130, the plurality of solder bumps 110, and the chip 100 as main components. The chip 100 may have the active surface 102 flip chip bonded and electrically connected to the substrate 130 through the solder bumps 110.

According to a method in accordance with an embodiment, a low residue no-clean flux composition with a high activity is used so that a solder bonding characteristic of the flux can be optimally exhibited, and at the same time, the flux residue after the reflow process can be reduced or minimized. Therefore, it is possible to effectively mitigate or prevent a problem of poor reliability due to the flux residue in a subsequent process.

The embodiment shown in FIGS. 2A to 2F is described with respect to a flip chip package process. However, a method in accordance with an embodiment may be applied to other processes, for example a semiconductor package process including a soldering process such as a BGA, an FCBGA, or a TSV package process.

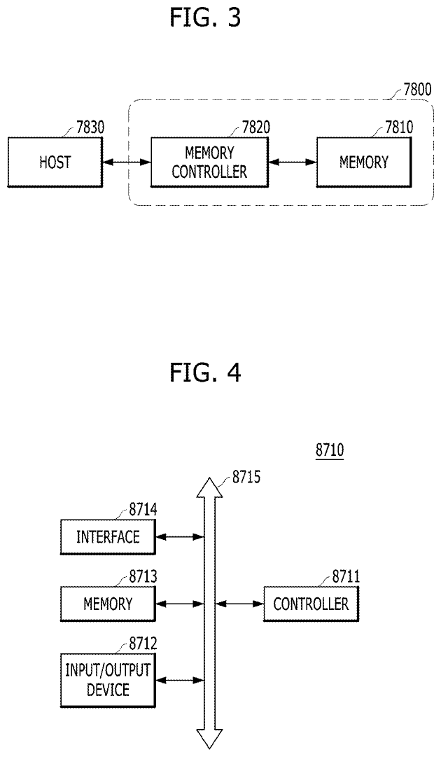

FIG. 3 shows a block diagram illustrating an electronic system including a memory card 7800 employing at least one semiconductor package according to an embodiment. The memory card 7800 includes a memory 7810 device, such as a nonvolatile memory device, and a memory controller 7820. The memory 7810 device and the memory controller 7820 may store data or read out the stored data. At least one of the memory 7810 device and the memory controller 7820 may include at least one semiconductor package fabricated according to a described embodiment.

The memory 7810 device may include nonvolatile memory to which the technology of the present disclosure is applied. The memory controller 7820 may control the memory 7810 device such that stored data is read out or data is stored in response to a read/write request from a host 7830.

FIG. 4 shows a block diagram illustrating an electronic system 8710 including at least one semiconductor package according to a described embodiment. The electronic system 8710 may include a controller 8711, an input/output device 8712, and a memory 8713 device. The controller 8711, the input/output device 8712, and the memory 8713 device may be coupled with one another through a bus 8715 providing a path through which data moves.

In an embodiment, the controller 8711 may include one or more microprocessor, digital signal processor, microcontroller, and/or logic device capable of performing the same functions as these components. The controller 8711 or the memory 8713 device may include one or more semiconductor packages fabricated according to embodiments of the present disclosure. The input/output device 8712 may include at least one selected among a keypad, a keyboard, a display device, a touchscreen, and so forth. The memory 8713 device is a device for storing data. The memory 8713 device may store data and/or commands to be executed by the controller 8711, and the like.

The memory 8713 device may include volatile memory, such as DRAM, and/or nonvolatile memory, such as flash memory. For example, a flash memory device may be mounted to an information processing system such as a mobile terminal or a desktop computer. The flash memory device may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 represents equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution), or Wibro (wireless broadband Internet).

The present teachings will now be more fully described with reference to the accompanying examples. It should be understood, however, that the following descriptions are illustrative only and should not be taken in any way as a restriction of the present teachings.

### EXAMPLES

### 1. Preparation of Flux Compositions

### (1) Preparation of Flux Compositions of Examples 1 to 20

In a 500 mL beaker, an aromatic resin, an activator, and a solvent were added according to the composition and content shown in Tables 1 and 2, dissolved at a temperature of 150° C., and mixed by stirring at 150 rpm for 60 minutes. The mixture was cooled to 30° C. or lower while maintaining the stirring rate to form the flux composition.

TABLE 1

| | Component (wt %) | | | | | | | | |
|---|---|---|---|---|---|---|---|---|---|
| | | | | | | Solvent | | | |
| | Aromatic resin | | | | | Diethylene | | | |
| | | | Methyl | | | glycol | Activator | | |
| | 4-Dodecyl | Benzyl | phenyl | Cinnamic | Phthalyl | monobutyl | Maleic | Malonic | |
| Example | phenol | alcohol | carbinol | alcohol | alcohol | ether | anhydride | anhydride | Total |
| 1 | 85.7 | | | | | 5.7 | 8.6 | | 100 |
| 2 | | 85.7 | | | | 5.7 | 8.6 | | 100 |
| 3 | | | 85.7 | | | 5.7 | 8.6 | | 100 |
| 4 | | | | 85.7 | | 5.7 | 8.6 | | 100 |
| 5 | | | | | 85.7 | 5.7 | 8.6 | | 100 |
| 6 | 85.7 | | | | | 5.7 | | 8.6 | 100 |
| 7 | | 85.7 | | | | 5.7 | | 8.6 | 100 |
| 8 | | | 85.7 | | | 5.7 | | 8.6 | 100 |
| 9 | | | | 85.7 | | 5.7 | | 8.6 | 100 |
| 10 | | | | | 85.7 | 5.7 | | 8.6 | 100 |

TABLE 2

| | Component (wt %) | | | | | | | | |
|---|---|---|---|---|---|---|---|---|---|
| | | | Solvent | | Activator | | | | |
| | | | Tripropylene | Diethylene | 1,4- | | | | |
| | Aromatic resin | | glycol | glycol | Cyclohexane | | | | |
| | 4-Dodecyl | Benzyl | monobutyl | monobutyl | dicarboxylic | Itaconic | Maleic | Malonic | |
| Example | phenol | alcohol | ether | ether | acid | acid | anhydride | anhydride | Total |
| 11 | 76.2 | 9.5 | | 5.7 | | | 8.6 | | 100 |
| 12 | 76.2 | 9.5 | 2.8 | 2.9 | | | 8.6 | | 100 |
| 13 | 76.2 | 9.5 | 2.8 | 2.9 | 1 | | 7.6 | | 100 |
| 14 | 76.2 | 9.5 | 2.8 | 2.9 | 3 | | 5.6 | | 100 |
| 15 | 76.2 | 9.5 | 2.8 | 2.9 | 5 | | 3.6 | | 100 |
| 16 | 76.2 | 9.5 | | 5.7 | | | | 8.6 | 100 |
| 17 | 76.2 | 9.5 | 2.8 | 2.9 | | | | 8.6 | 100 |
| 18 | 76.2 | 9.5 | 2.8 | 2.9 | | 1 | | 7.6 | 100 |
| 19 | 76.2 | 9.5 | 2.8 | 2.9 | | 3 | | 5.6 | 100 |
| 20 | 76.2 | 9.5 | 2.8 | 2.9 | | 5 | | 3.6 | 100 |

### (2) Preparation of Flux Compositions of Comparative Examples 1 and 2

Flux compositions of Comparative Examples 1 and 2 were prepared according to the composition and content shown in Table 3 by using the same method as for Examples 1 to 20 described as above. The components used in Comparative Examples 1 and 2 are materials which have been used in conventionally known no-clean low residue flux composition.

TABLE 3

| | Component (wt %) | | | | |
|---|---|---|---|---|---|
| | | Diethylene | | | |
| | | glycol | | | |
| Comparative | Isobornyl | monobutyl | Acid | | |
| Example | cyclohexanol | ether | 2PZ-CNS | C11-CNS | Total |
| 1 | 85.7 | 5.7 | 8.6 | | 100 |
| 2 | 85.7 | 5.7 | | 8.6 | 100 |

2PZ-CNS: 1-Cyanoethyl-2-phenylimidazolium trimellitate
C11-CNS: 1-Cyanoethyl-2-undecylimidazolium trimellitate

### 2. Evaluation of Characteristics of Flux Composition

In order to evaluate characteristics of the flux compositions of Examples 1 to 20, and Comparative Examples 1 and 2, the viscosity, the tackiness, the soldering characteristics, the acid value, and the residues after the reflow process were measured.

### (1) Viscosity Measurement

0.5 mL of each of the flux compositions of Examples 1 to 20, and Comparative Examples 1 and 2 was disposed in a viscometer (Brookfield DV-II), and the viscosity value was measured at a speed of 5 rpm using a spindle (Spindle No. 51). After repeating the measurement three times, the average value is shown in Table 4.

TABLE 4

| | Viscosity (MPa) |
|---|---|
| Example 1 | 19,574 |
| Example 2 | 8,627 |
| Example 3 | 7,178 |
| Example 4 | 25,361 |
| Example 5 | 38,214 |
| Example 6 | 17,308 |
| Example 7 | 7,684 |
| Example 8 | 6,478 |
| Example 9 | 23,117 |
| Example 10 | 35,794 |
| Example 11 | 19,574 |
| Example 12 | 15,215 |
| Example 13 | 16,263 |
| Example 14 | 17,862 |
| Example 15 | 18,487 |
| Example 16 | 17,308 |
| Example 17 | 13,145 |
| Example 18 | 14,308 |
| Example 19 | 15,620 |
| Example 20 | 16,827 |
| Comparative Example 1 | 15,161 |
| Comparative Example 2 | 16,632 |

From the result shown in Table 4, it can be found that the flux compositions of Examples 1 to 20 have similar or superior viscosity ranges in terms of workability as compared to the flux compositions of Comparative Examples 1 and 2.

Wafer chips have various sizes and thicknesses, and the bump size and the pitch vary depending on device types. Accordingly, ranges of the viscosity and the tackiness required for the flux composition may vary depending on the type of wafer chip and process characteristics. However, the flux composition having the viscosity and the tackiness in a specific narrow range cannot cover a margin for various processes. The flux compositions of Examples 1 to 20 can exhibit desirable various viscosity values within a wide range required for engineering by controlling the components and the content. Therefore, the flux compositions of Examples 1 to 20 can exhibit excellent viscosity characteristics rather than the flux compositions of Comparative Examples 1 and 2 having the viscosity in a narrow range.

### (2) Tackiness Measurement

The tackiness of the flux compositions of Examples 1 to 10, and Comparative Examples 1 and 2 was measured. The tackiness was measured by using a universal testing machine (UBM) under a condition according to JIS-Z-3284 (Load: 50 g, Down Speed: 2 mm/s, Up Speed: 10 mm/s). Each composition was printed at a thickness of 0.2 mm and the printed film was pressed with a probe having a diameter of 5.1 mm for 0.2 seconds to measure the tackiness. The results are shown in Table 5.

TABLE 5

| | Tackiness (gf) |
|---|---|
| Example 1 | 185 |
| Example 2 | 172 |
| Example 3 | 176 |
| Example 4 | 180 |
| Example 5 | 182 |
| Example 6 | 179 |
| Example 7 | 159 |
| Example 8 | 163 |
| Example 9 | 173 |
| Example 10 | 177 |
| Comparative Example 1 | 172 |
| Comparative Example 2 | 176 |

From the results shown in Table 5, it can be found that the flux compositions of Examples 1 to 10 have similar or superior viscosity ranges in terms of the tackiness compared to the flux compositions of Comparative Examples 1 and 2.

The flux compositions of Examples 1 to 10 can exhibit various tackiness values in a wide range by controlling the components and the content so that it can be applied to various processes which require the tackiness in a wide range according to the type of the wafer chip and process characteristics. Therefore, the flux compositions of Examples 1 to 10 can exhibit excellent tackiness characteristics rather than the flux compositions of Comparative Examples 1 and 2 having the tackiness in a narrow range.

### (3) Soldering Characteristics Measurement

1) In order to find the effect of the aromatic resin on the soldering characteristics, a Wetting/Non-Wetting Test was performed on the flux compositions of Examples 1 to 10, and Comparative Examples 1 and 2. A dummy chip having a bump size of 100 μm and a pitch of 150 μm was dipped into the flux composition at a thickness of 70 μm. The dummy chip was attached to a 140×140×0.2 mm copper clad laminated board printed circuit substrate (PCB), and then a reflow process was performed in a reflow oven (Peak Temp. 250° C.) under a condition of O₂ of 100 ppm or less. After the reflow process, the dummy chip attached to the copper clad of the PCB was removed to check if the solder was bonded. Upon repeating 30 times, number of dummy chips to which the solder was not bonded was tabulated. The results are shown in Table 6.

TABLE 6

| | Number of Non-Wetting chips/ | Fail |
|---|---|---|
| | Number of total chips | ratio (%) |
| Example 1 | 2/30 | 6.7 |
| Example 2 | 3/30 | 10.0 |
| Example 3 | 4/30 | 13.3 |
| Example 4 | 4/30 | 13.3 |
| Example 5 | 3/30 | 10.0 |
| Example 6 | 2/30 | 6.7 |
| Example 7 | 4/30 | 13.3 |
| Example 8 | 4/30 | 13.3 |
| Example 9 | 3/30 | 10.0 |
| Example 10 | 4/30 | 13.3 |
| Comparative Example 1 | 6/30 | 20.0 |
| Comparative Example 2 | 5/30 | 16.6 |

From the results shown in Table 6, when the content of the activator (the acid in case of Comparative Examples 1 and 2) is the same as each other, it can be found that the flux compositions of Examples 1 to 10 can exhibit superior soldering characteristics compared to the flux compositions of Comparative Examples 1 and 2.

2) In order to find the soldering characteristics for bonding bumps with a smaller size, a Wetting/Non-Wetting Test was performed on the flux compositions of Examples 1 to 10, and Comparative Examples 1 and 2. A dummy chip having a bump size of 40 μm and a pitch of 60 μm was dipped into the flux composition at a thickness of 40 μm. The dummy chip was attached to a 140×140×0.2 mm copper clad laminated board printed circuit substrate (PCB), and then a reflow process was performed in a reflow oven (Peak Temp. 250° C.) under a condition of O₂ of 100 ppm or less. After the reflow process, the dummy chip attached to the copper clad of the PCB was removed to check the number of dummy chips to which the solder was not bonded. The results are shown in Table 7.

TABLE 7

| | Number of Non-Wetting chips/ | Fail |
|---|---|---|
| | Number of total chips | ratio (%) |
| Example 11 | 6/30 | 20.0 |
| Example 12 | 6/30 | 20.0 |
| Example 13 | 1/30 | 3.3 |
| Example 14 | 0/30 | 0 |
| Example 15 | 0/30 | 0 |
| Example 16 | 7/30 | 23.3 |
| Example 17 | 7/30 | 23.3 |
| Example 18 | 2/30 | 6.6 |
| Example 19 | 0/30 | 0 |
| Example 20 | 0/30 | 0 |
| Comparative Example 1 | 8/30 | 26.6 |
| Comparative Example 2 | 6/30 | 20.0 |

From the result shown in Table 7, it can be found that the flux compositions of Examples 1 to 10 can exhibit superior soldering characteristics compared to the flux compositions of Comparative Examples 1 and 2 in terms of bonding fine bumps having a smaller size and pitch.

### (4) Acid Value Measurement

For the flux compositions of Examples 11 to 20, and Comparative Examples 1 and 2, the acid value was measured in order to determine acidity affecting the soldering characteristics. 10 g of each flux composition was dissolved in 100 mL of a mixture of ethanol and methanol (2:1). Then, 4-5 drops of phenolphthalein were added in and stirred. Then, after titrating 0.1 N KOH solution using a burette, the acid value was measured according to the following equation:

$$Acid value ( mg / g ) = \frac{5.611 \times ( a - b ) \times f}{S}$$

wherein S: amount of sample (g), a: initial amount of 0.1N KOH (mL), b: remaining amount of 0.1N KOH (mL) after titration, and f: titer of 0.1N KOH (usually 1).

The results are shown in Table 8.

TABLE 8

| | acid value |
|---|---|
| Example 11 | 81.2 |
| Example 12 | 81.0 |
| Example 13 | 86.8 |
| Example 14 | 95.5 |
| Example 15 | 100.2 |
| Example 16 | 83.7 |
| Example 17 | 83.8 |
| Example 18 | 88.5 |
| Example 19 | 97.2 |
| Example 20 | 101.9 |
| Comparative Example 1 | 65.3 |
| Comparative Example 2 | 66.4 |

As shown in Table 8, the flux compositions of Examples 11 to 20 have higher acid value than the flux compositions of Comparative Examples 1 and 2. Therefore, it can be found that the flux compositions of Examples 11 to 20 can exhibit superior soldering characteristics compared to the flux compositions of Comparative Examples 1 and 2.

(5) Measurement of Residue after the Reflow Process

For the flux compositions of Examples 1 to 20, and Comparative Examples 1 and 2, the residue after the reflow process was measured. After weighing each composition in an aluminum pan, the reflow process (Peak Temp.: 250° C.) was performed in a reflow oven (1707MK III, Heller). The weight of the residue of each composition remaining after the reflow process was measured. The ratio of the residue to the weight of the composition is shown in Table 9.

TABLE 9

| | Residue after the reflow process (wt %) |
|---|---|
| Example 1 | 4.7 |
| Example 2 | 3.9 |
| Example 3 | 3.5 |
| Example 4 | 5.1 |
| Example 5 | 5.5 |
| Example 6 | 4.8 |
| Example 7 | 4.2 |
| Example 8 | 3.7 |
| Example 9 | 5.3 |
| Example 10 | 5.6 |
| Example 11 | 4.7 |
| Example 12 | 4.8 |
| Example 13 | 4.9 |
| Example 14 | 5.1 |
| Example 15 | 5.2 |
| Example 16 | 4.8 |
| Example 17 | 4.6 |
| Example 18 | 4.3 |
| Example 19 | 4.0 |
| Example 20 | 3.8 |
| Comparative Example 1 | 6.4 |
| Comparative Example 2 | 6.3 |

From the results shown in Table 9, it can be found that, after the reflow process, the residue of the flux compositions of Examples 1 to 20 is reduced as compared to the flux compositions of Comparative Examples 1 and 2. Therefore, in accordance with the embodiments, it is possible to mitigate or prevent a problem of poor reliability caused by the residue remaining after the reflow process.

Although various embodiments have been described for illustrative purposes, it will be apparent to those skilled in the art that various changes and modifications may be made without departing from the spirit and scope of the present teachings as defined in the following claims.

What is claimed is:

1. A flux composition comprising:
an aromatic resin including one benzene ring and one or two hydroxyl (—OH) groups;
an activator selected from a group consisting of a dicarboxylic acid and a dicarboxylic anhydride; and
a solvent.

2. The flux composition of claim 1, wherein the aromatic resin:
imparts a viscosity and a tackiness to the flux composition; and
is capable of being volatilized during a reflow process.

3. The flux composition of claim 1, wherein the activator is capable of:
removing an oxide film by reduction;
activating surfaces to be bonded; and
being volatilized during a reflow process.

4. The flux composition of claim 1, wherein the aromatic resin is selected from a group consisting of compounds of Formulae 1 to 5:

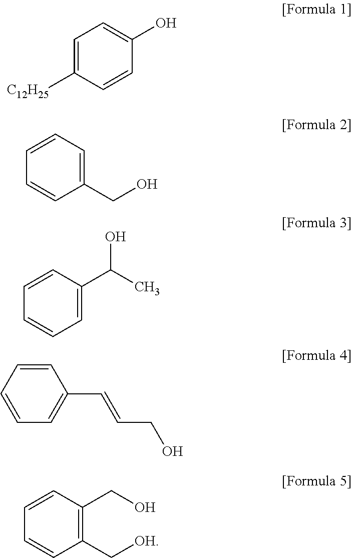

5. The flux composition of claim 1, wherein the activator is selected from a group consisting of compounds of Formulae 6 to 9:

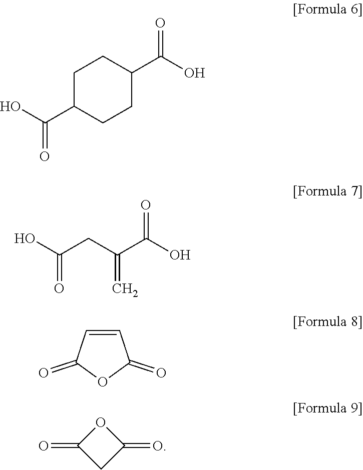

6. The flux composition of claim 1, wherein the solvent comprises at least one of isopropyl alcohol, ethanol, acetone, toluene, xylene, ethyl acetate, monoglycol ether, butyl carbitol, cellosolve, butyl cellosolve, glycol ether, hexyldiglycol, (2-ethylhexyl)diglycol, phenylglycol, octanediol, α-terpineol, propylene glycol, β-terpineol, tetraethylene glycol dimethyl ether, tris(2-ethylhexyl) trimellitate, bis(2-ethylhexyl) sebacate, diethylene glycol monohexyl ether, diethylene glycol monobutyl ether, and tripropylene glycol monobutyl ether.

7. The flux composition of claim 1, wherein the flux composition comprises:
60-90 percent by weight (wt %) of the aromatic resin;
1-10 wt % of the activator; and
5-40 wt % of the solvent.

8. The flux composition of claim 1, wherein the flux composition is capable of being applied to soldering in a semiconductor package process including at least one of:
a ball grid array (BGA);
a flip chip ball grid array (FCBGA);
a wafer level package (WLP); and
a through silicon via (TSV).

9. The flux composition of claim 1, wherein the flux composition is such that, after a reflow process involving the flux composition, a residue of the flux composition is in an amount of 6.0 percent by weight (wt %) or less based on a total weight of the flux composition.

10. The flux composition of claim 1, wherein a viscosity and a tackiness of the flux composition is capable of being selectively controlled by adjusting relative amounts of the aromatic resin and the activator in the flux composition.

11. A method for fabricating a semiconductor package comprises performing a soldering process using a flux composition, wherein the flux composition comprises:
an aromatic resin including one benzene ring and one or two hydroxyl (—OH) groups;
an activator selected from a group consisting of a dicarboxylic acid and a dicarboxylic anhydride; and
a solvent.

12. The method of claim 11, wherein the aromatic resin:
imparts a viscosity and a tackiness to the flux composition; and
is capable of being volatilized during a reflow process.

13. The method of claim 11, wherein the activator is capable of:
removing an oxide film by reduction;
activating surfaces to be bonded; and
being volatilized during a reflow process.

14. The method of claim 11, wherein the aromatic resin is selected from a group consisting of compounds of Formulae 1 to 5:

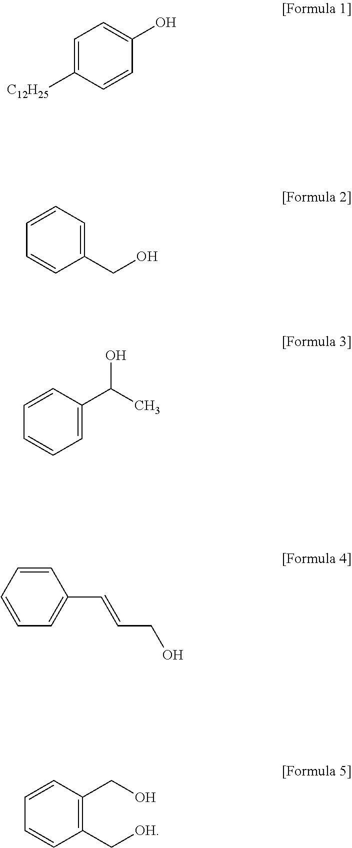

15. The method of claim 11, wherein the activator is selected from a group consisting of compounds of Formulae 6 to 9:

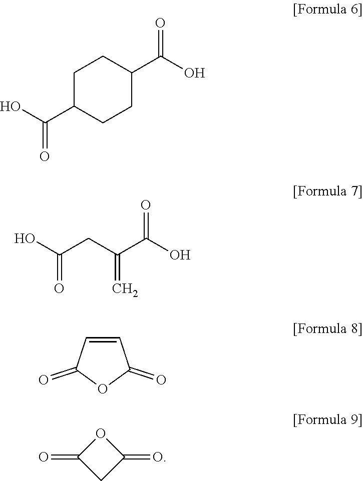

16. The method of claim 11, wherein the solvent comprises at least one of isopropyl alcohol, ethanol, acetone, toluene, xylene, ethyl acetate, monoglycol ether, butyl carbitol, cellosolve, butyl cellosolve, glycol ether, hexyldiglycol, (2-ethylhexyl)diglycol, phenylglycol, octanediol, α-terpineol, propylene glycol, β-terpineol, tetraethylene glycol dimethyl ether, tris(2-ethylhexyl) trimellitate, bis(2-ethylhexyl) sebacate, diethylene glycol monohexyl ether, diethylene glycol monobutyl ether, and tripropylene glycol monobutyl ether.

17. The method of claim 11, wherein the flux composition comprises:
60-90 percent by weight (wt %) of the aromatic resin;
1-10 wt % of the activator; and
5-40 wt % of the solvent.

18. The method of claim 11, wherein the flux composition is such that, after a reflow process involving the flux composition, a residue of the flux composition is in an amount of 6.0 percent by weight (wt %) or less based on a total weight of the flux composition.

19. The method of claim 11, wherein performing the soldering process using the flux composition comprises applying the flux composition to soldering a semiconductor package comprising at least one of:
a ball grid array (BGA);
a flip chip ball grid array (FCBGA);
a wafer level package (WLP); and
a through silicon via (TSV).

20. A method for fabricating a semiconductor package, the method comprising:
forming solder bumps over an active surface of a chip;
applying a flux composition over a surface of the solder bumps;
providing a substrate having a first surface where first pads are formed and a second surface where second pads are formed;
aligning the chip with the substrate such that the solder bumps of the chip are in contact with the first pads of the substrate; and
performing a reflow process on the aligned chip and substrate,
wherein the flux composition comprises:
an aromatic resin including one benzene ring and one or two hydroxyl (—OH) groups;
an activator selected from a group consisting of a dicarboxylic acid and a dicarboxylic anhydride; and
a solvent.

21. The method of claim 20, wherein the chip is flip chip bonded and electrically connected to the substrate through the reflow process.

22. The method of claim 20, further comprising forming an underfill layer by applying an underfill layer material in a gap between the substrate and the chip after the reflow process.

23. The method of claim 22, further comprising forming an array of solder balls over the second pads after the forming of the underfill layer.

24. The method of claim 20, wherein the aromatic resin is selected from a group consisting of compounds of Formulae 1 to 5:

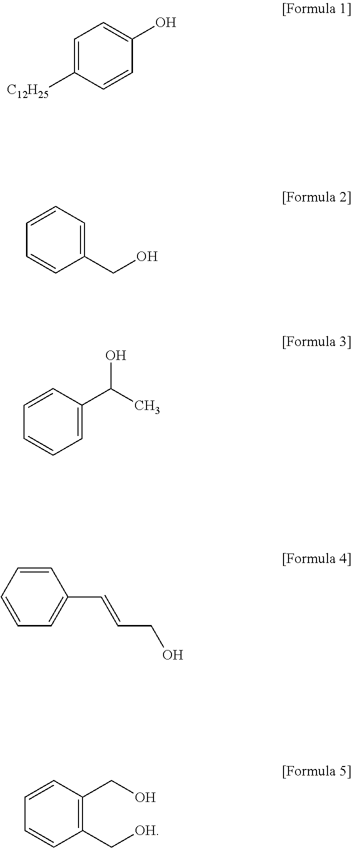

25. The method of claim 20, wherein the activator is selected from a group consisting of compounds of Formulae 6 to 9:

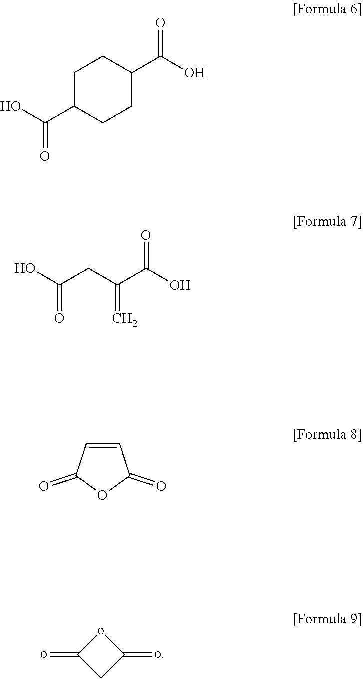

26. The method of claim 20, wherein the solvent includes at least one of isopropyl alcohol, ethanol, acetone, toluene, xylene, ethyl acetate, monoglycol ether, butyl carbitol, cellosolve, butyl cellosolve, glycol ether, hexyldiglycol, (2-ethylhexyl)diglycol, phenylglycol, octanediol, α-terpineol, propylene glycol, β-terpineol, tetraethylene glycol dimethyl ether, tris(2-ethylhexyl) trimellitate, bis(2-ethylhexyl) sebacate, diethylene glycol monohexyl ether, diethylene glycol monobutyl ether, and tripropylene glycol monobutyl ether.

27. The method of claim 20, wherein the flux composition comprises:
60-90 percent by weight (wt %) of the aromatic resin;
1-10 wt % of the activator; and
5-40 wt % of the solvent.

28. The method of claim 20, wherein the flux composition is such that, after a reflow process involving the flux composition, a residue of the flux composition is in an amount of 6.0 percent by weight (wt %) or less based on a total weight of the flux composition.
